(19) United States
(12) Patent Application Publication
(10) Pub. No.: US 2026/0367498 A1
(43) Pub. Date: Nov. 19, 2026

(54) AMORPHOUS CAPPING LAYER STRUCTURE FOR LITHOGRAPHY MASK BLANK

(71) Applicant: Taiwan Semiconductor Manufacturing Company, Ltd., Hsinchu (TW)

(72) Inventors: Pei-Cheng HSU, Taipei (TW); Sih-Wei CHANG, Hsinchu (TW); Ken-Hsien HSIEH, Taipei (TW); Hsin-Chang LEE, Zhubei (TW)

(73) Assignee: Taiwan Semiconductor Manufacturing Company, Ltd., Hsinchu (TW)

(21) Appl. No.: 19/754,008

(22) Filed: Jul. 24, 2026

Related U.S. Application Data
(63) Continuation of application No. 18/828,344, filed on Sep. 9, 2024.

(51) Int. Cl. G03F 1/24

(52) U.S. Cl. CPC G03F 1/24

(57) ABSTRACT

A multi-layer reflective structure is disposed over a substrate. An amorphous capping layer is disposed over the multi-layer reflective structure and includes platinum (Pt), iridium (Ir), rhodium (Rh), or ruthenium (Ru) alloyed with Pt, Ir, or Rh.

### RELATED APPLICATION

This application is a Continuation application of U.S. patent application Ser. No. 18/828,344 filed on Sep. 9, 2024, the entire content of which is incorporated herein by reference.

### BACKGROUND

The semiconductor integrated circuit (IC) industry has experienced rapid growth. Technological advances in IC materials and design have produced generations of ICs where each generation has smaller and more complex circuits than the previous generation. These advances, however, have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the smallest component (or line) to be created using a fabrication process) has decreased.

As the semiconductor device sizes continue to shrink, for example in the nanometer (nm) nodes, traditional lithography technologies have optical restrictions, which leads to resolution issues and may not achieve the desired lithography performance. In comparison, extreme ultraviolet (EUV) lithography achieves much smaller device sizes. Existing EUV lithography, however, may still face certain challenges. For example, the capping layer of existing EUV masks may become easily damaged, which may degrade lithography performance and/or shorten the lifespan of the EUV mask.

Therefore, while existing EUV lithography systems and methods have been generally adequate for their intended purposes, there remains room for improvement.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic view of a lithography system constructed in accordance with some embodiments of the present disclosure.

FIGS. 2, 3, 4, 5, 6, 7, and 8 illustrate cross-sectional views of a lithography mask at various stages of fabrication according to embodiments of the present disclosure.

FIGS. 9, 10, 11, 12, and 13 illustrate cross-sectional views of various capping layers according to embodiments of the present disclosure.

FIG. 14 is a flowchart illustrating a method of fabricating a reflective multilayer structure for lithography in accordance with some embodiments of the present disclosure.

FIG. 15 is a flowchart illustrating a method of manufacturing a lithography mask in accordance with some embodiments of the present disclosure.

### DETAILED DESCRIPTION

It is to be understood that the following disclosure provides many different embodiments, or examples, for implementing different features of the present application. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B, and one from C, unless otherwise explained.

Extreme ultraviolet (EUV) lithography has become widely used due to its ability to achieve small semiconductor device sizes. However, conventional systems and methods of performing EUV lithography may still face various challenges. For example, conventional EUV systems employ a lithography mask configured to perform EUV lithography. Among other components, the EUV lithography mask includes a capping layer that is configured to protect some of the other components (e.g., a multi-layer reflective structure) of the EUV lithography mask. Some conventional EUV lithography masks implement the capping layer using a polycrystalline material that may become damaged during the various EUV lithography processes.

Conventional capping layers with polycrystalline material are susceptible to chemical diffusion through grain boundaries and result in damage to the multi-layer reflective structure. A material with a polycrystalline structure has multiple crystallites (also referred to as “grains”) of varying sizes and orientations. A grain boundary refers to an interface between two of such grains or crystallites. During lithography processes, for example during dry etching and cleaning (or as a result thereof), the grain boundaries of the polycrystalline capping layer may crack, shrink, or otherwise become rough (as opposed to having a smooth flat surface). These damages to the capping layer may adversely impact the lithography performance, for example with respect to the critical dimension (CD) metrology during wafer printing. The damages to the capping layer may also shorten the lifespan of the EUV lithography mask since the EUV lithography masks with capping layer damages are less able to withstand particle removal by cleaning or electron beam (E-beam) repair. When EUV lithography masks are frequently replaced due to excessive damage, this results in a cost increase in semiconductor fabrication.

To alleviate these problems discussed above, the present disclosure forms an EUV lithography mask having a capping layer with an amorphous structure. The amorphous structure allows the capping layer to be more durable and to better withstand the various EUV lithography processes without becoming damaged, and can improve EUV lithography performance and prolong the lifespan of the EUV lithography mask. The high chemical durability of the amorphous structure of the capping layer of the EUV lithography mask can help protect the reflectivity of the multi-layer reflective structure from damage. The various aspects of the present disclosure will be discussed below in greater detail with reference to the drawing figures.

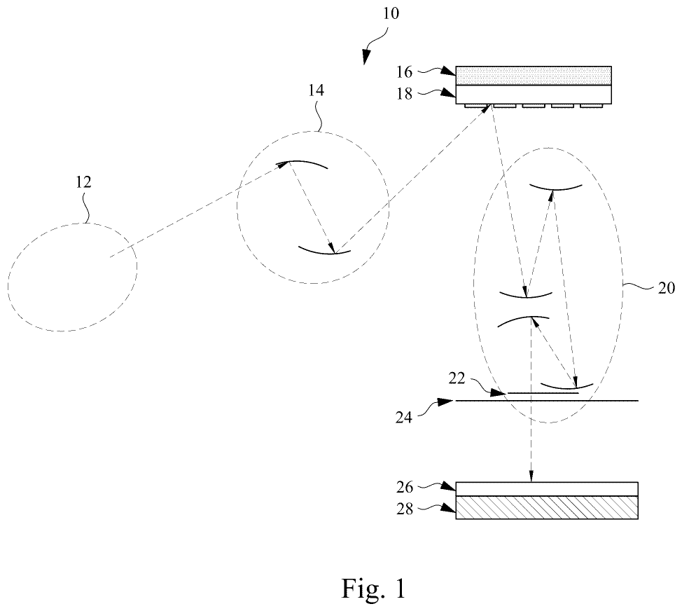

An EUV lithography system according to embodiments of the present disclosure is discussed below with reference to FIG. 1. A schematic view diagram of an EUV lithography system 10, structured in accordance with some embodiments is shown in FIG. 1. The EUV lithography system 10 is generally referred to as a scanner that is configured to perform lithography exposure processes with respective radiation source and exposure mode. The EUV lithography system 10 is designed to expose a photoresist layer by EUV light or EUV radiation. The photoresist layer is a material sensitive to the EUV light. The EUV lithography system 10 employs a radiation source 12 to generate EUV light, such as EUV light having a wavelength ranging between about 1 nm and about 100 nm. In certain examples, radiation source 12 generates an EUV light with a wavelength between 10 to 121 nm. Accordingly, the radiation source 12 is also referred to as an EUV radiation source 12.

The lithography system 10 also employs an illuminator 14. In various embodiments, the illuminator 14 includes various refractive optic components, such as a single lens or a lens system having multiple lenses (zone plates) or alternatively reflective optics (for EUV lithography system), such as a single mirror or a mirror system having multiple mirrors to direct light from the radiation source 12 onto a mask stage 16, particularly to a EUV lithography mask 18 secured on the mask stage 16. The mask stage 16 is configured to secure an EUV lithography mask 18. In some embodiments, the mask stage 16 includes an electrostatic chuck (e-chuck) to secure the EUV lithography mask 18. In the present embodiment, where the radiation source 12 generates light in the EUV wavelength range, the illuminator 14 employs reflective optics. In some embodiments, the illuminator 14 includes a dipole illumination component.

In some embodiments, illuminator 14 is operable to configure the mirrors to provide proper illumination to the EUV lithography mask 18. In one example, the mirrors of the illuminator 14 are switchable to reflect EUV light to different illumination positions. In some embodiments, a stage before the illuminator 14 additionally includes other switchable mirrors that are controllable to direct the EUV light to different illumination positions with the mirrors of the illuminator 14. In certain embodiments, illuminator 14 is configured to provide an on-axis illumination (ONI) to the EUV lithography mask 18. In one example, a disk illuminator 14 with partial coherence o being at most 0.3 is employed. In some other embodiments, the illuminator 14 is configured to provide an off-axis illumination (OAI) to the EUV lithography mask 18. For example, the illuminator 14 is a dipole illuminator. The dipole illuminator has a partial coherence o of at most 0.3 in some embodiments.

In the embodiment of FIG. 1, the lithography system 10 is an EUV lithography system, and the EUV lithography mask 18 is a reflective mask. In the present disclosure, the terms mask, photomask, and reticle are used interchangeably to refer to the same item. One exemplary structure of the EUV lithography mask 18 is provided for illustration. The EUV lithography mask 18 includes a substrate with a suitable material, such as a low thermal expansion material (LTEM) or fused quartz. In various examples, the LTEM includes TiO₂ doped SiO₂ or other suitable materials with low thermal expansion. In some embodiments, the LTEM includes 5%-20% by weight TiO₂ and has a thermal coefficient of expansion lower than about 1.0×10^{-6/°} C. For example, in some embodiments, the TiO₂ doped SiO₂ material of the LTEM has a coefficient of thermal expansion such that it varies by less than 60 parts per billion for every 1 degree Celsius of temperature change. Of course, other suitable materials having thermal coefficient of expansion that is equal to or less than TiO₂ doped SiO₂ are contemplated.

The EUV lithography mask 18 also includes a multi-layer reflective structure deposited on the substrate. The multi-layer reflective structure includes a plurality of film pairs, such as molybdenum-silicon (Mo/Si) film pairs (e.g., a layer of molybdenum above or below a layer of silicon in each film pair). Alternatively, the multi-layer reflective structure includes molybdenum-beryllium (Mo/Be) film pairs, or other suitable materials that are configurable to reflect the EUV light.

The EUV lithography mask 18 includes a capping layer that is disposed on the multi-layer reflective structure for protection of the multi-layer reflective structure and/or the layers there below. Conventional EUV masks may implement a capping layer having a polycrystalline structure. As discussed above, the polycrystalline structure for capping layers may be prone to damage, for example, the grain boundaries of the polycrystalline capping layer may shrink, become roughened, or cracked as a result of lithography processes such as etching and cleaning, and as a result permit harsh chemicals to diffuse through the grain boundaries and damage the multi-layer reflective structure. Polycrystalline structures are susceptible to damage by chemical reactions during mask cleaning and repair processes. For example, a sulfuric acid and hydrogen peroxide mixture used during a mask cleaning operation is corrosive and causes grain shrinkage allowing the corrosive sulfuric acid and hydrogen peroxide mixture to penetrate the grain boundaries of the polycrystalline surface. Moreover, a SiO₂ layer may form on an upmost Si layer of the multi-layer reflective structure due to penetration of the sulfuric acid and hydrogen peroxide mixture. A damaged capping layer and underlying multi-layer reflective structure result may result in decreased EUV reflectivity and the lifespan of the EUV mask may be shortened.

Conventional polycrystalline structures for capping layers are also susceptible to hydrogen radical attack in an EUV scanner environment. The damage to the polycrystalline capping layer may cause problems in fabrication such as diminished critical dimension (CD) metrology. The EUV lithography mask itself may also suffer from a reduced lifespan due to the damage to the polycrystalline capping layer.

According to embodiments of the present disclosure, the capping layer of the EUV lithography mask 18 includes an amorphous structure. In that regard, amorphous structures are non-crystalline and may lack a well-defined geometric shape since their constituents are not arranged in an ordered manner. As such, amorphous structures may not have the grain boundaries that exist in polycrystalline structures. Since fabrication-induced damages typically occur at the grain boundaries, the lack of grain boundaries of the amorphous capping layer substantially prevents or at least reduces the damages that could occur as a result of chemical corrosion and diffusion into the multi-layer reflective structure in some embodiments. Moreover, the amorphous structures of embodiments of the present disclosure better withstand hydrogen radical attack in an EUV scanner environment. Consequently, lithography performance may be improved, and the lifespan of the EUV lithography mask 18 may be prolonged, which reduces the cost of semiconductor fabrication.

In some embodiments, the amorphous capping layer is formed by first forming an amorphous layer on the multi-layer reflective structure. In other embodiments, the amorphous capping layer is formed by first treating the upper surface of the multi-layer reflective structure (for example by treating it with a plasma), and thereafter forming the amorphous capping layer on the treated surface of the multi-layer reflective structure.

The EUV lithography mask 18 further includes an absorption layer (also referred to as an absorber layer) deposited over the amorphous capping layer. The absorption layer is patterned to define a layer of an integrated circuit (IC). Alternatively, another reflective layer is deposited over the multi-layer reflective structure and is patterned to define a layer of an integrated circuit, thereby forming an EUV phase shift mask.

As shown in FIG. 1, the lithography system 10 also includes a projection optics module (or projection optics box (POB) 20 for imaging the pattern of the EUV lithography mask 18 on to a target 26 (e.g., a semiconductor substrate) secured on a substrate stage 28 of the lithography system 10. The POB 20 has refractive optics (such as for UV lithography system) or alternatively reflective optics (such as for EUV lithography system) in various embodiments. The light directed from the EUV lithography mask 18, diffracted into various diffraction orders and carrying the image of the pattern defined on the mask, is collected by the POB 20. In some embodiments, the POB 20 includes a magnification of less than one (thereby the size of the “image” on a target (such as target 26 discussed below) is smaller than the size of the corresponding “object” on the mask). The illuminator 14 and the POB 20 are collectively referred to as an optical module of the lithography system 10.

The lithography system 10 also includes a pupil phase modulator 22 to modulate the optical phase of the light directed from the EUV lithography mask 18 so that the light has a phase distribution on a projection pupil plane 24. In the optical module, there is a plane with field distribution corresponding to a Fourier Transform of the object (the EUV lithography mask 18 in the present case). This plane is referred to as the projection pupil plane. The pupil phase modulator 22 provides a mechanism to modulate the optical phase of the light on the projection pupil plane 24. In some embodiments, the pupil phase modulator 22 includes a mechanism to tune the reflective mirrors of the POB 20 for phase modulation. In certain embodiments, the mirrors of the POB 20 are switchable and are controlled to reflect the EUV light, thereby modulating the phase of the light through the POB 20.

In some embodiments, the pupil phase modulator 22 utilizes a pupil filter placed on the projection pupil plane 24. A pupil filter filters out specific spatial frequency components of the EUV light from the EUV lithography mask 18. Particularly, the pupil filter is a phase pupil filter that functions to modulate the phase distribution of the light directed through the POB 20. However, utilizing a phase pupil filter is limited in some lithography systems (such as an EUV lithography system) since the materials of the phase pupil filter absorb EUV light.

As discussed above, lithography system 10 also includes substrate stage 28 to secure the target 26 to be patterned, such as a semiconductor substrate. In the present embodiment, the semiconductor substrate is a semiconductor wafer, such as a silicon wafer or other type of wafer. The target 26 is coated with a resist layer sensitive to the radiation beam, such as EUV light in the present embodiment. Various components including those described above are integrated and are operable to perform lithography exposing processes. In some embodiments, the lithography system 10 includes other modules or is integrated with (or coupled with) other modules.

The EUV lithography mask 18 and the method of fabricating the same are further described in accordance with some embodiments. In certain embodiments, the mask fabrication process includes a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve the desired design of a layer of an integrated circuit (IC). The patterned mask is then used to transfer circuit patterns (e.g., the design of a layer of an IC) onto a semiconductor wafer. The patterns are transferred over and over onto multiple wafers through various lithography processes. A set of masks is used to construct a complete IC.

The EUV lithography mask 18 includes a suitable structure, such as a binary intensity mask (BIM) and phase-shifting mask (PSM) in various embodiments. An example BIM includes absorptive regions (also referred to as opaque regions) and reflective regions, patterned to define an IC pattern to be transferred to the target. In the opaque regions, an absorber is present, and an incident light is almost fully absorbed by the absorber. In the reflective regions, the absorber is removed, and the incident light is diffracted by a multilayer (multi-layer reflective structure). In certain embodiments, the PSM is an attenuated PSM (AttPSM) or an alternating PSM (AltPSM). An exemplary PSM includes a first reflective layer (such as a multi-layer reflective structure) and a second reflective layer patterned according to an IC pattern. In some examples, an AttPSM has a reflectivity of 2%-15% from its absorber, while an AltPSM has a reflectivity of larger than 50% from its absorber.

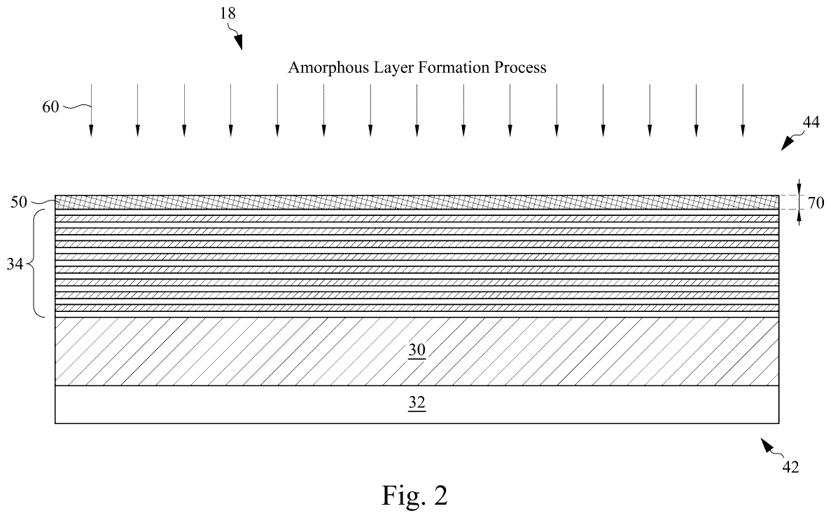

FIGS. 2-8 are cross-sectional side views of a lithography mask at various stages of fabrication according to embodiments of the present disclosure. Referring to FIG. 2, the EUV lithography mask 18 in FIG. 1 is illustrated in more detail. The EUV lithography mask 18 includes a substrate 30. In certain embodiments, the substrate includes an LTEM with TiO2 doped SiO₂, and/or other suitable low thermal expansion materials. In some embodiments, a conductive layer 32 is additionally disposed on an underside 42 (also referred to as a backside) of the LTEM substrate 30 for the electrostatic chucking purpose. In one example, the conductive layer 32 includes chromium nitride (CrN). In other embodiments, other suitable compositions are possible, such as a tantalum-containing material.

The EUV lithography mask 18 includes a multi-layer reflective structure 34 disposed over a side 44 (also referred to as a front side) of the LTEM substrate 30. The multi-layer reflective structure 34 is selected such that it provides a high reflectivity to a selected radiation type/wavelength. The multi-layer reflective structure 34 includes a plurality of film pairs, such as Mo/Si film pairs (e.g., a layer of molybdenum above or below a layer of silicon in each film pair). Alternatively, the multi-layer reflective structure 34 includes Mo/Be film pairs or any materials with refractive index difference being highly reflective at EUV wavelengths.

Still referring to FIG. 2, an amorphous layer 50 is formed on the upper surface of the uppermost layer of the multi-layer reflective structure 34. The amorphous layer 50 helps the layer to be formed thereon (i.e., the amorphous capping layer) to achieve an amorphous structure. This is because the lattice arrangement (e.g., whether it is a single crystal structure, a polycrystal structure, or an amorphous structure) of a thin layer (which the capping layer will be) is significantly affected by the lattice arrangement of the layer underneath. In other words, if the amorphous layer 50 is formed to have an amorphous structure, the layer to be formed thereon (i.e., the capping layer) is also likely to have an amorphous structure. This is referred to as “substrate tuning,” as the amorphous layer 50 is considered an “amorphous substrate” for the amorphous capping layer to be formed thereon.

In certain embodiments, the amorphous layer 50 is formed using an amorphous layer formation process 60. In some embodiments, the amorphous layer formation process 60 includes an epitaxial growth process. In some other embodiments, the amorphous layer formation process 60 includes a deposition process. In some examples, the deposition process includes an atomic layer deposition (ALD) process, for example, an ALD process that is performed at a low temperature in a range between about 26 degrees Celsius and about 60 degrees Celsius. In other examples, the deposition process also includes a chemical vapor deposition (CVD) process, for example, an atmospheric pressure CVD (APCVD) process, a low-pressure CVD (LPCVD) process, a laser-enhanced CVD (LECVD) process, and/or a plasma-enhanced CVD (PECVD) process. In certain examples, the deposition process includes a physical vapor deposition (PVD) process, for example, an electrically heated evaporation (thermal evaporation) process, a pulsed laser deposition process, an electron-beam evaporation process, a molecular beam epitaxy process, an ion beam assisted evaporation process, a discharge based deposition process such as sputtering or arc evaporation, or ion beam deposition (IBD).

The amorphous layer 50 is formed to have a thickness 70. The value of the thickness 70 is tunable by adjusting the various parameters of the amorphous layer formation process 60, for example, a time duration of deposition, etc. In some embodiments, the thickness 70 is tuned to be in a range between about 0.1 nanometers (nm) and about 4 nm, for example between about 2 nm and about 4 nm. Such a thickness range for the amorphous layer 50 helps ensure that the amorphous layer 50 is sufficiently thick to help the capping layer to be formed thereon to achieve the amorphous structure, but not too thick to significantly affect the reflectivity of the multi-layer reflective structure 34. In some embodiments, the uppermost layer of the multi-layer reflective structure 34 is a silicon layer, and the amorphous layer 50 is formed directly on the uppermost surface of this uppermost silicon layer of the multi-layer reflective structure 34. In other embodiments, the amorphous layer 50 includes amorphous silicon, amorphous silicon oxide (SiO₂), or amorphous silicon nitride (Si₃N₄).

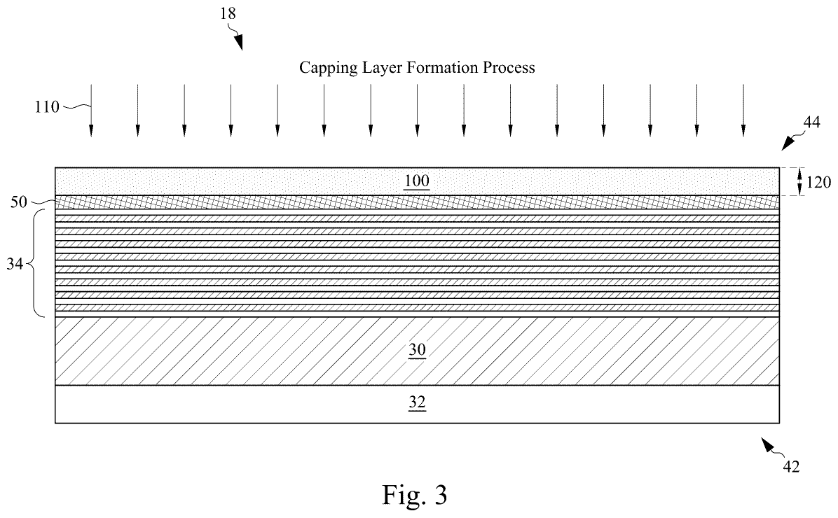

Referring now to FIG. 3, a capping layer 100 is formed over the amorphous layer 50, for example, formed directly on the upper surface of the amorphous layer 50. In some embodiments, the capping layer 100 is formed by a capping layer formation process 110. In some embodiments, the capping layer formation process 110 includes an epitaxial growth process, a CVD process (such as APCVD, LPCVD, LECVD, or PECVD), or a PVD process (such as electrically heated evaporation, pulsed laser deposition, electron-beam evaporation, molecular beam epitaxy, ion beam assisted evaporation, sputtering, arc evaporation, or ion beam deposition (IBD). As discussed above, the presence of the amorphous layer 50 below the capping layer 100 can make it easier for the capping layer 100 to achieve an amorphous structure.

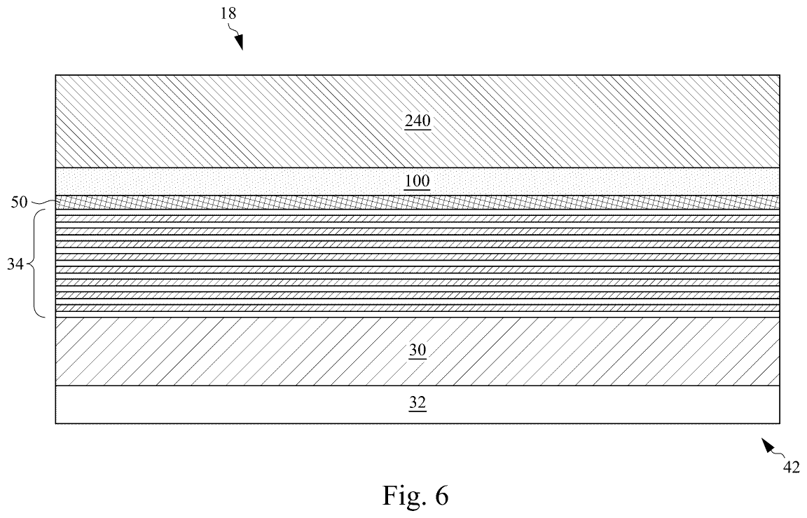

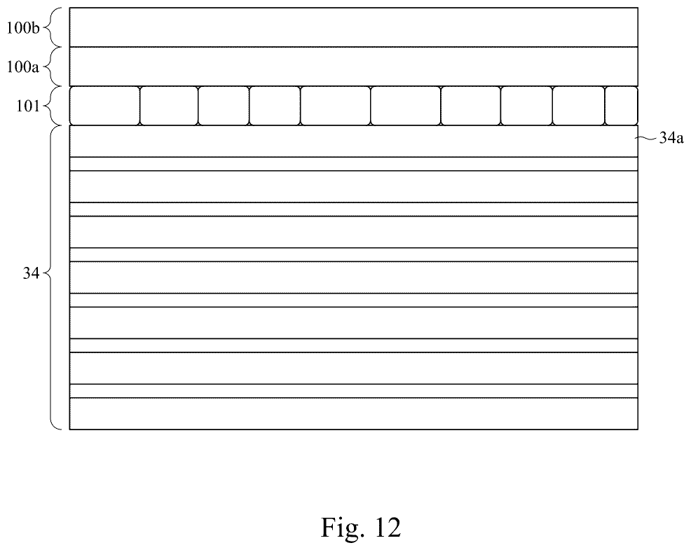

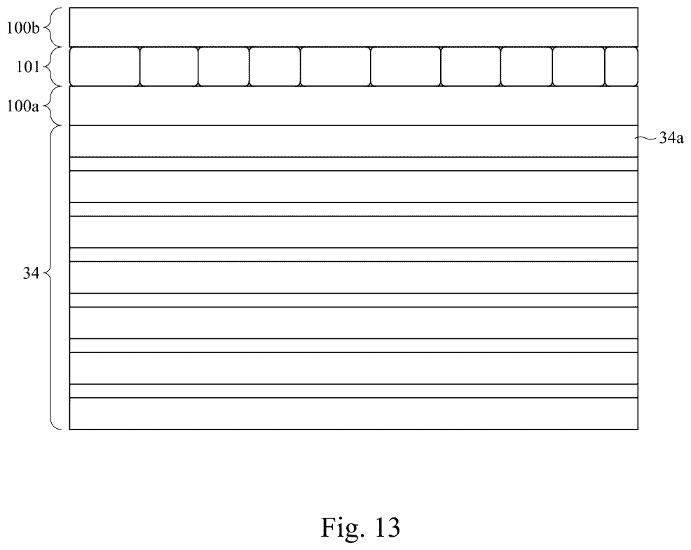

The capping layer 100 is formed to have a thickness 120. The value of the thickness 120 is tunable by adjusting the various parameters of the capping layer formation process 110, for example, a time duration of deposition, etc. In some embodiments, the thickness 120 is tuned to be in a range between about 1 nm and about 6 nm, for example between about 2 nm and about 4 nm. Such a thickness range for the capping layer 100 helps ensure that the capping layer 100 is sufficiently thick to adequately protect the multi-layer reflective structure 34 underneath, but not too thick to significantly affect the reflectivity of the multi-layer reflective structure 34. As shown in the embodiments of FIGS. 6-11, one or more amorphous capping layers are disposed over the multi-layer reflective structure 34. As shown in the embodiments of FIGS. 12 and 13, an amorphous capping layer and a polycrystalline capping layer are disposed over the multi-layer reflective structure 34.

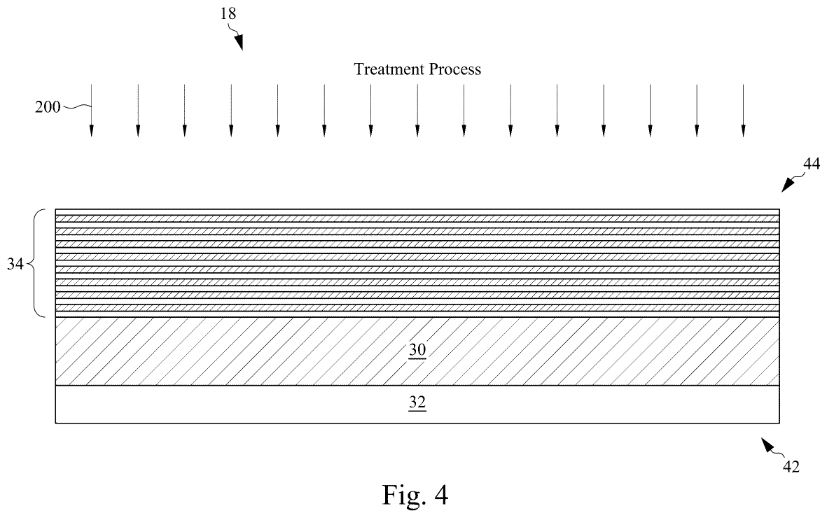

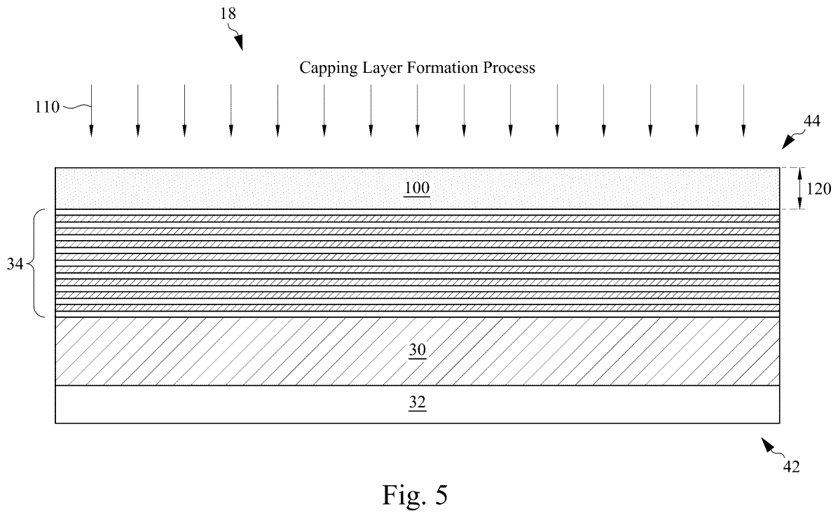

It is understood that FIGS. 2 and 3 illustrate merely one embodiment of forming an amorphous capping layer 100. Another embodiment of forming the amorphous capping layer 100 is shown in FIGS. 4 and 5. Referring to FIG. 4, the multi-layer reflective structure 34 is formed over the LTEM substrate 30. A treatment process 200 is performed to treat the upper surface of an uppermost layer (e.g., a silicon layer of the uppermost Si/Mo film pair) of the multi-layer reflective structure 34. The treatment of the uppermost layer of the multi-layer reflective structure 34 facilitates the formation of the amorphous capping layer. In other words, if the uppermost layer of the multi-layer reflective structure 34 had not been treated by the treatment process 200, the capping layer that is to be formed thereon is more likely to have a polycrystalline structure, which as discussed above is undesirable. Here, the treatment of the uppermost layer of the multi-layer reflective structure 34 means that the capping layer to be formed thereon is an amorphous structure. As discussed above, an amorphous capping layer is desirable because it can reduce defects in the EUV mask 18, improve lithography performance, and prolong the lifespan of the EUV mask 18. As shown in the embodiments of FIGS. 6-13, one or more capping layers are disposed over the multi-layer reflective structure 34.

One reason for the treatment of the multi-layer reflective structure 34 facilitating the formation of an amorphous structure thereon involves free energy. When a film is formed on a substrate, there is a surface-free energy of the substrate, a free energy of the film, and a free energy of an interface between the substrate and the film. A delta free energy is defined as the free energy of the film plus (+) the free energy of the interface minus (−) the surface free energy of the substrate. A delta-free energy of less than 0 is associated with a Volmer-Weber mode of film formation, where “islands” appear first, and then these islands coalesce into a continuous film. This is undesirable, as the film formed in this mode is more likely to have a polycrystalline structure and therefore be prone to damage. On the other hand, a delta free energy of greater than 0 is associated with a Frank-Van der Merwe mode of film formation, where the film is grown layer-by-layer, where each layer mimics the structure of the layer below. This is more desirable, as the one or more layers formed in this manner have an amorphous structure. Here, the treatment process 200 de-wets the uppermost surface of the multi-layer reflective structure 34 and causes the delta free energy to be greater than 0, which facilitates the layer-by-layer amorphous film formation of the capping layer 100.

In some embodiments, the treatment process 200 involves applying plasma to the uppermost layer (e.g., a silicon layer of the Si/Mo film pair) of the multi-layer reflective structure 34. For example, the plasma includes an argon (Ar) plasma, an oxygen plasma, or a nitrogen plasma. The plasma treatment of the upper surface of the multi-layer reflective structure 34 removes stains, grease, or other contaminants from the upper surface, and therefore improves the uniformity of the upper surface. In some embodiments, the plasma process is performed at a temperature range between about 28 degrees Celsius and about 35 degrees Celsius, and with a time duration range between about 5 seconds and about 60 seconds. Such a temperature range and a time duration range are not randomly chosen but specifically configured so as to optimize the effects of the plasma treatment of the uppermost layer of the multi-layer reflective structure 34. For example, if the temperature range and/or the time duration range are too long or too short, the formation of the amorphous capping layer over the treated surface of the multi-layer reflective structure 34 may be disrupted.

Referring now to FIG. 5, the capping layer 100 is formed on the uppermost layer of the multi-layer reflective structure 34. Again, in some embodiments, the capping layer 100 is formed using the capping layer formation process 110 discussed above, which includes an epitaxial growth process, a CVD process, or a PVD process. In certain embodiments, the amorphous structure is formed by a PVD process including a low sputtering power and low deposition temperature. In other embodiments, process conditions for the PVD include a low-temperature deposition in a range of room temperature (e.g., 18 to 24 °C) to 300 °C and at low sputtering power in a range of 200 Watts to 10 kilowatts. In some embodiments, a low deposition temperature is ideal for the amorphous structure of the capping layer 100.

As discussed above, the capping layer 100 in some embodiments has an amorphous structure and the process parameters of the capping layer formation process 110 are configured such that the capping layer 100 has the thickness 120 in a range between about 1 nm and about 6 nm.

It is understood that the embodiment discussed above with reference to FIGS. 2 and 3 and the embodiment discussed above with reference to FIGS. 4 and 5 are combined to facilitate the formation of the capping layer 100. For example, in some embodiments, the treatment process 200 is performed to treat the multi-layer reflective structure 34. Thereafter, the amorphous layer 50 (e.g., an amorphous Si layer, an amorphous silicon nitride layer, or an amorphous silicon oxide layer) is formed on the treated surface of the multi-layer reflective structure 34. The treated surface of the multi-layer reflective structure 34 may also facilitate the formation of the amorphous structure for the amorphous layer 50. Thereafter, in some embodiments, the capping layer 100 is formed on the amorphous layer 50.

In other embodiments, the amorphous capping layer is formed over the multi-layer reflective structure without the amorphous layer 50 or treatment process. The amorphous structure of the capping layer is achieved by way of doping with nitrogen (N), boron (B), oxygen (O), or oxynitride (ON) during the formation of the capping layer. In other embodiments, deposition conditions are controlled to allow the formation of the amorphous structure. In certain embodiments, process conditions for a PVD include a low-temperature deposition in a range of room temperature (e.g., 18 to 24 °C) to 300 °C and at low sputtering power in a range of 200 Watts to 10 kilowatts. In some embodiments, a low deposition temperature is ideal for the amorphous structure of the capping layer 100.

Regardless of how the capping layer 100 is formed to achieve an amorphous structure, further fabrication processing is performed to complete the formation of the EUV mask 18. For example, referring now to FIG. 6, an absorber layer 240 (also referred to as an absorption layer) is formed over the capping layer 100. In some embodiments, the absorber layer 240 absorbs the EUV radiation directed onto the EUV lithography mask 18. In various embodiments, the absorber layer is made of tantalum boron nitride (TaBN), tantalum boron oxide (TaBO), chromium (Cr), radium (Ra), or a suitable oxide or nitride (or alloy) of one or more of the following materials: actinium, radium, tellurium, zinc, copper, aluminum, nickel, and nickel alloys.

It is understood that in some embodiments, a buffer layer is optionally formed between the capping layer 100 and the absorber layer 240. The buffer layer may serve as an etching-stop layer in a patterning or repairing process of the absorber layer 240. The buffer layer may have different etching characteristics from the absorber layer disposed there above. In some embodiments, the buffer layer includes ruthenium, RuB, RuSi, chromium, chromium oxide, or chromium nitride.

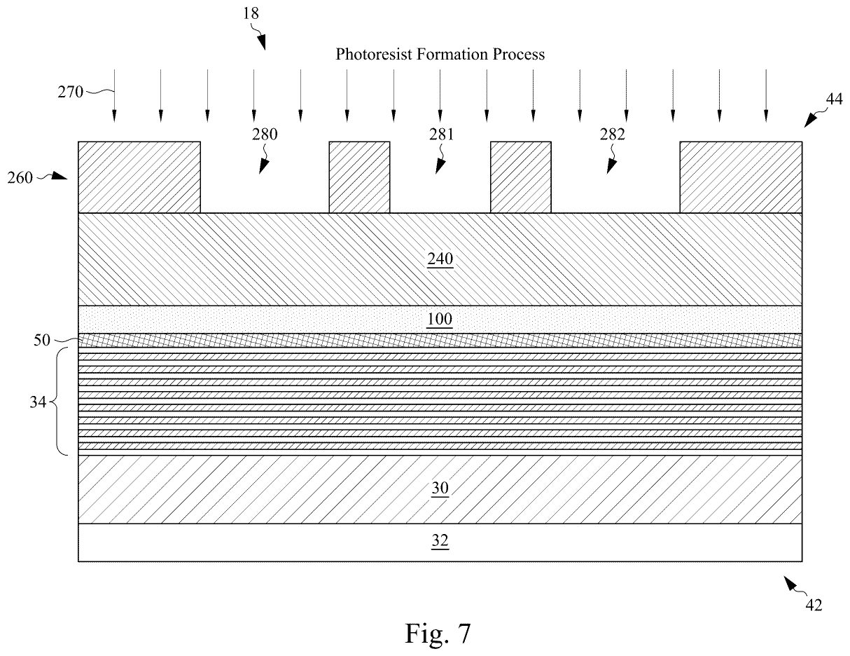

Referring now to FIG. 7, a photoresist layer 260 is formed over the absorber layer 240 using a photoresist formation process 270. In some embodiments, the photoresist formation process 270 includes a spin-coating process. In some examples, the photoresist layer 260 is an EUV photoresist (e.g., sensitive to radiation in the EUV range). The photoresist layer 260 is patterned into a plurality of portions separated by a plurality of openings, for example, openings 280, 281, and 282. In some embodiments, the patterning of the photoresist layer 260 includes an electron beam (E-beam) exposure process, a post-exposure bake process, and a photoresist developing process.

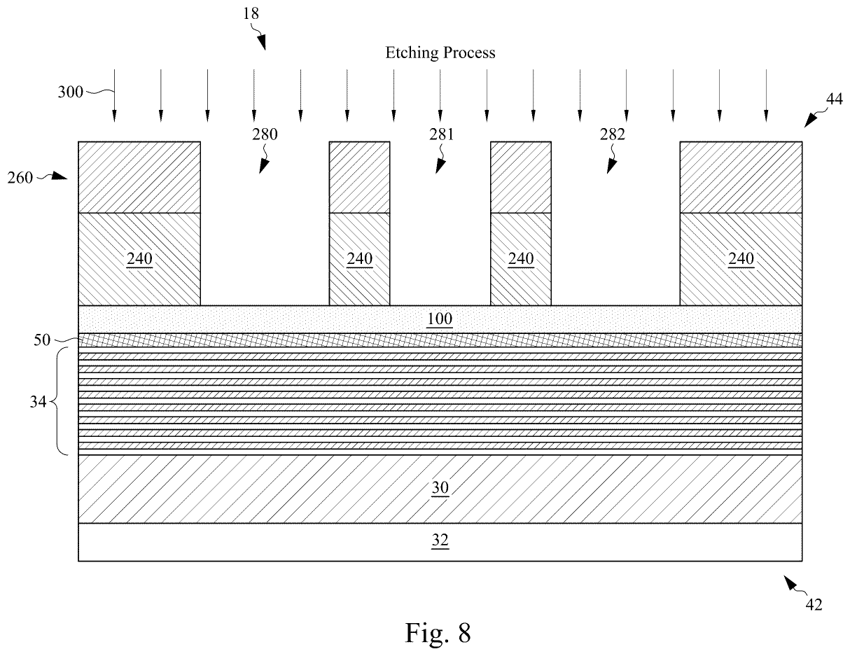

Referring now to FIG. 8, the absorber layer 240 is etched using an etching process 300, with the patterned photoresist layer 260 serving as an etching mask. In other words, the openings 280-282 are vertically extended through the absorber layer 240 until portions of the capping layer 100 are exposed by the openings 280-282. In some embodiments, the etching process 300 includes a dry etching process. The capping layer 100 effectively serves as an etching-stop layer for the etching process 300. For conventional EUV lithography masks where the capping layer has a polycrystalline structure, the etching process 300 may damage the capping layer due to the polycrystalline structure having grain boundaries. For example, shrinkage may occur between adjacent grains of the polycrystalline capping layer, tiny cracks may appear at the exposed upper surfaces of the polycrystalline capping layer, or exposed portions of the polycrystalline capping layer may have excessively roughened upper surfaces. These defects may adversely impact the lithography performance and/or shorten the lifespan of the EUV lithography mask. In comparison, the capping layer 100 herein is formed to have an amorphous structure, which allows it to withstand the etching process 300 without incurring significant damage. For example, even after the etching process 300 is performed, the upper surfaces of the exposed portions of the capping layer 100 may be substantially flatter and smoother compared to the polycrystalline capping layer used for conventional EUV lithography masks.

In certain embodiments, additional processing is performed to remove the patterned photoresist layer 260. In some embodiments, a photoresist removal process (not shown) includes a photoresist stripping or ashing process. Moreover, in certain embodiments, the photoresist formation process (not shown) includes forming another patterned photoresist layer over the EUV lithography mask 18. Additional etching of the EUV lithography mask is performed and a photoresist removal process is performed, followed by one or more cleaning processes to clean the EUV lithography mask 18, for example, to remove contaminant particles disposed on the EUV lithography mask 18. In certain embodiments, portions of the capping layer 100 are exposed. Chemicals (e.g., solutions that contain oxygen and/or hydrogen) used in one or more cleaning processes could seep into the shrunk, cracked, or roughened surfaces of the capping layer and therefore further damage the capping layer if the capping layer had been implemented using a polycrystalline material. However, since the uppermost capping layer 100 herein is implemented using an amorphous material, the cleaning processes will not cause damage to the capping layer 100 according to embodiments of the present disclosure. In some embodiments, following one or more cleaning operations, one or more wafer printing processes are performed using the EUV lithography mask 18. In some embodiments, the EUV lithography mask 18 is used as a lithography mask in one or more EUV lithography processes to define or pattern various features on a semiconductor wafer. During EUV lithography processing, outgassing products may come into contact with various components of the EUV lithography mask 18, including the exposed surfaces of the capping layer 100. Had the capping layer 100 been implemented using only a polycrystalline material, such exposed surfaces may have already suffered extensive damage (e.g., excessive shrinkage, roughness, or cracks) by the time the wafer printing processes were performed. The outgassing products may be absorbed or diffuse onto the exposed (and damaged) surfaces of the capping layer because the shrunk or roughened surfaces of such a capping layer could trap the outgassing products. The presence of the outgassing products on the damaged capping layer surfaces could contaminate the EUV lithography mask and further deteriorate the performance of the lithography process. For example, the reflectivity of the multi-layer reflective structure 34 would have been undesirably altered due to the outgassing products stuck on the capping layer surfaces. Again, the EUV lithography mask 18 of the present disclosure does not suffer from this problem because the amorphous capping layer 100 is substantially free of damage, and therefore the outgassing products generated by the wafer printing processes will not infiltrate the exposed surfaces of the capping layer 100. Consequently, the present disclosure alleviates the undesirable contamination of the EUV lithography mask 18.

In some embodiments, the amorphous capping layer 100 includes a platinum group metal that improves chemical corrosion resistance. In certain embodiments, the amorphous structure of the capping layer includes a platinum group metal or platinum group metal alloy. In other embodiments, the platinum group metal or platinum group metal alloy is doped with nitrogen (N), boron (B), oxygen (O), or oxynitride (ON). In other embodiments, the platinum group metal or platinum group metal alloy is doped with niobium (Nb) or chromium (Cr). The novel material of the amorphous structure of the capping layer can reduce chemical corrosion and/or diffusion which can lead to damage of the capping layer and the underlying multi-layer reflective structure. Moreover, the amorphous structure of the novel materials of the capping layer extends the lifetime of the EUV mask. In certain embodiments, the capping layer includes a platinum group metal such as platinum (Pt), ruthenium (Ru), rhodium (Rh), iridium (Ir), and alloys thereof. These platinum group metals and their alloys provide increased chemical resistance of the capping layer due to their amorphous microstructure which can improve the longevity of the capping layer. In certain embodiments, these platinum group metals and their alloys are doped with nitrogen (N), boron (B), oxygen (O), or oxynitride (ON) when forming an amorphous structure. In other embodiments, the platinum group metals are doped with other metals including niobium (Nb) or chromium (Cr) that are resistant to chemical damage. As described below, one or more amorphous capping layers are disposed over the multi-layer reflective structure.

Non-limiting examples of platinum group metals and metals alloys include Pt, Ru, Rh, Ir, RuN, IrN, RhN, PtN, RuO, IrO, RhO, PtO, RuB, IrB, RhB, PtB, RuON, IrON, RhON, PtON, RuNbN, IrNbN, RhNbN, PtNbN, RuRhN, IrRhN, PtRhN, RuNbO, IrNbO, RhNbO, PtNbO, RuRhO, IrRhO, PtRhO, RuNbON, IrNbON, RhNbON, PtNbON, RuRhON, IrRhON, PtRhON, RuNbB, IrNbB, RhNbB, PtNbB, RuRhB, IrRhB, PtRhB, RuNbCrN, IrNbCrN, RhNbCrN, PtNbCrN, RuRhCrN, IrRhCrN, PtRhCrN, RuNbCrO, IrNbCrO, RhNbCrO, PtNbCrO, RuRhCrO, IrRhCrO, PtRhCrO, RuNbCrON, IrNbCrON, RhNbCrON, PtNbCrON, RuRhCrON, IrRhCrON, PtRhCrON, RuNbCrB, IrNbCrB, RhNbCrB, PtNbCrB, RuRhCrB, IrRhCrB, and PtRhCrB.

In certain embodiments, a single amorphous capping layer is comprised of Ru, Ir, Rh, or Pt and has a thickness ranging between 1 and 6 nm. In other embodiments, the capping layer is comprised of a platinum group metal and doped with one or more dopants selected from N, O, B, and ON. In some embodiments, the dopant is less than or equal to about 40 atomic % (at %), for example about 2 at %, about 5 at %, about 10 at %, about 20 at %, about 30 at %, or about 40 at %. Non-limiting examples of doped platinum group metals include RuN, IrN, RhN, PtN, RuO, IrO, RhO, PtO, RuB, IrB, RhB, PtB, RuON, IrON, RhON, and PtON.

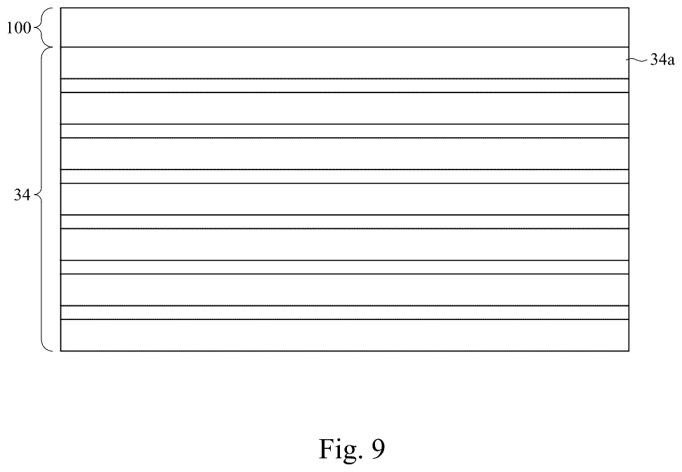

In other embodiments, a single amorphous capping layer is comprised of a platinum group metal alloy doped with one or more dopants selected from N, O, B, and ON. In certain embodiments, the dopant is less than or equal to about 40 atomic % (at %), for example about 2 at %, about 5 at %, about 10 at %, about 20 at %, about 30 at %, or about 40 at %. The platinum group metal alloy of this embodiment is alloyed with another platinum group metal and doped with Nb. In certain embodiments, a second platinum group metal is provided in the alloy in an amount less than or equal to about 40 atomic % (at %), for example about 5 at %, about 10 at %, about 20 at %, about 30 at %, or about 40 at %. In some embodiments, Nb is present in the alloy in an amount less than or equal to about 10 at %, for example, about 1 at %, about 5 at %, or about 10 at %. The addition of Nb helps increase the etching resistance of the capping layer 100. Non-limiting examples of the doped platinum metal or platinum metal alloy include RuNbN, IrNbN, RhNbN, PtNbN, RuRhN, IrRhN, PtRhN, RuNbO, IrNbO, RhNbO, PtNbO, RuRhO, IrRhO, PtRhO, RuNbON, IrNbON, RhNbON, PtNbON, RuRhON, IrRhON, PtRhON, RuNbB, IrNbB, RhNbB, PtNbB, RuRhB, IrRhB, and PtRhB. The single capping layer in this embodiment ranges between 1 and 6 nm in thickness. FIG. 9 illustrates an example of the single capping layer disposed over the multi-layer reflective structure 34.

In other embodiments, a single amorphous capping layer is comprised of a platinum group metal doped with N, O, B, or ON. The dopant is less than or equal to about 40 atomic % (at %), for example about 2 at %, about 5 at %, about 10 at %, about 20 at %, about 30 at %, or about 40 at %. In certain embodiments, the platinum group metal is alloyed with a second platinum group metal and doped with either Nb or Cr. In other embodiments, when a second platinum group metal is included in the alloy, it is present in an amount less than or equal to about 40 atomic % (at %), for example about 5 at %, about 10 at %, about 20 at %, about 30 at %, or about 40 at %. In other embodiments, a platinum group metal is doped with both Nb and Cr. In certain embodiments, Nb is doped in an amount less than or equal to about 10 at %, for example, about 1 at %, about 5 at %, or about 10 at %, and Cr is doped in an amount less than or equal to about 10 at %, for example, about 1 at %, about 5 at %, or about 10 at %. Non-limiting examples of the doped platinum metal or alloy include RuNbCrN, IrNbCrN, RhNbCrN, PtNbCrN, RuRhCrN, IrRhCrN, PtRhCrN, RuNbCrO, IrNbCrO, RhNbCrO, PtNbCrO, RuRhCrO, IrRhCrO, PtRhCrO, RuNbCrON, IrNbCrON, RhNbCrON, PtNbCrON, RuRhCrON, IrRhCrON, PtRhCrON, RuNbCrB, IrNbCrB, RhNbCrB, PtNbCrB, RuRhCrB, IrRhCrB, and PtRhCrB. The single capping layer in this embodiment ranges between 1 and 6 nm in thickness. FIG. 9 shows an example of the single capping layer disposed over the multi-layer reflective structure 34. Moreover, in certain embodiments, the uppermost Si layer 34a of the multi-layer reflective structure 34 first undergoes a treatment process 200, or an amorphous layer 50 is formed on the upper surface of the uppermost layer 34a of the multi-layer reflective structure 34 before forming a capping layer.

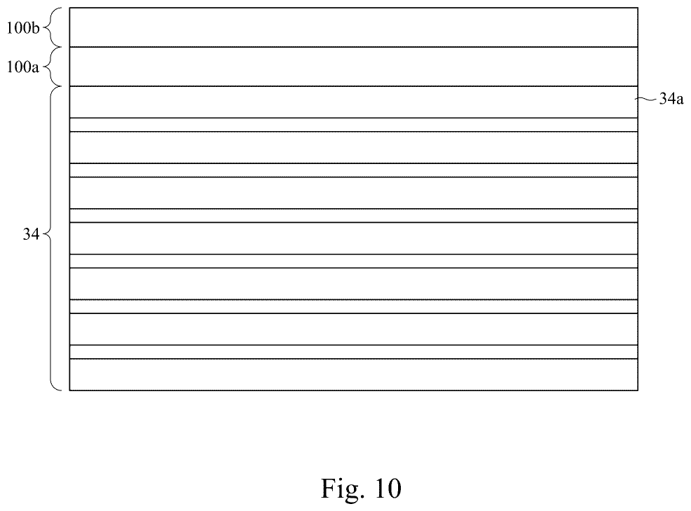

In certain embodiments, the amorphous capping layer is a bi-layer. FIG. 10 shows an example of the bi-layer capping layer 100a/100b disposed over the multi-layer reflective structure 34. The thickness of each capping layer ranges between 1 and 3 nm. In some embodiments, each capping layer is comprised of the same material, whereas in other embodiments, the material for each capping layer is different. In some embodiments, where two capping layers are formed, a first capping layer includes a first material and a second capping layer includes a second material. In some embodiments, the first and second materials are selected from Ru, Ir, Rh, Pt, RuN, IrN, RhN, PtN, RuO, IrO, RhO, PtO, RuB, IrB, RhB, PtB, RuON, IrON, RhON, PtON, RuNbN, IrNbN, RhNbN, PtNbN, RuRhN, IrRhN, PtRhN, RuNbO, IrNbO, RhNbO, PtNbO, RuRhO, IrRhO, PtRhO, RuNbON, IrNbON, RhNbON, PtNbON, RuRhON, IrRhON, PtRhON, RuNbB, IrNbB, RhNbB, PtNbB, RuRhB, IrRhB, PtRhB, RuNbCrN, IrNbCrN, RhNbCrN, PtNbCrN, RuRhCrN, IrRhCrN, PtRhCrN, RuNbCrO, IrNbCrO, RhNbCrO, PtNbCrO, RuRhCrO, IrRhCrO, PtRhCrO, RuNbCrON, IrNbCrON, RhNbCrON, PtNbCrON, RuRhCrON, IrRhCrON, PtRhCrON, RuNbCrB, IrNbCrB, RhNbCrB, PtNbCrB, RuRhCrB, IrRhCrB, and PtRhCrB. The at % amounts of the metals and dopants in each capping layer of the bi-layer are similar to those described above for the single capping layer embodiments.

In certain embodiments, a first amorphous capping layer 100a is disposed over the uppermost Si layer 34a of the multi-layer reflective structure 34. In one embodiment, the first amorphous capping layer is comprised of RuNB. The second amorphous capping layer 100b is disposed over the first capping layer 100a and is comprised of Rh. In yet another embodiment, the first and second amorphous capping layers 100a and 100b both comprise RhN. The atomic percentages of the individual metals and dopants in each amorphous capping layer of this embodiment are similar to what is described above for the single capping layer embodiment.

FIG. 10 shows an example of a bi-layer amorphous capping layer 100a/100b disposed over the multi-layer reflective structure 34. In certain embodiments, the uppermost Si layer 34a of the multi-layer reflective structure 34 first undergoes a treatment process 200, or an amorphous layer 50 is formed on the upper surface of the uppermost layer 34a of the multi-layer reflective structure 34 before forming a capping layer. While in other embodiments, the amorphous capping layer is formed over the multi-layer reflective structure by doping or a controlled PVD process.

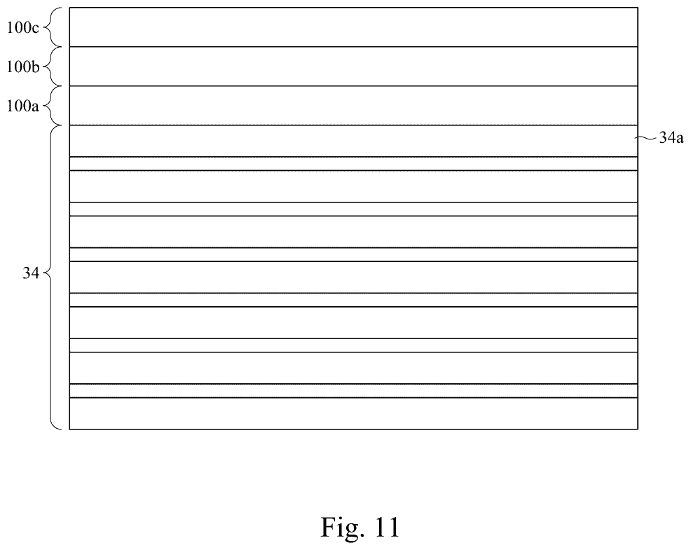

In other embodiments, the amorphous capping layer is a tri-layer, as shown in FIG. 11. The thickness of each capping layer ranges between 1 and 3 nm. In certain embodiments, each capping layer is comprised of the same material, whereas in other embodiments, the material for each capping layer is different. In some embodiments, where three capping layers are formed, a first capping layer 100a includes a first material, a second capping layer 100b includes a second material, and a third capping layer 100c comprises a third material. In some embodiments, the first, second, and third materials are selected from Ru, Ir, Rh, Pt, RuN, IrN, RhN, PtN, RuO, IrO, RhO, PtO, RuB, IrB, RhB, PtB, RuON, IrON, RhON, PtON, RuNbN, IrNbN, RhNbN, PtNbN, RuRhN, IrRhN, PtRhN, RuNbO, IrNbO, RhNbO, PtNbO, RuRhO, IrRhO, PtRhO, RuNbON, IrNbON, RhNbON, PtNbON, RuRhON, IrRhON, PtRhON, RuNbB, IrNbB, RhNbB, PtNbB, RuRhB, IrRhB, PtRhB, RuNbCrN, IrNbCrN, RhNbCrN, PtNbCrN, RuRhCrN, IrRhCrN, PtRhCrN, RuNbCrO, IrNbCrO, RhNbCrO, PtNbCrO, RuRhCrO, IrRhCrO, PtRhCrO, RuNbCrON, IrNbCrON, RhNbCrON, PtNbCrON, RuRhCrON, IrRhCrON, PtRhCrON, RuNbCrB, IrNbCrB, RhNbCrB, PtNbCrB, RuRhCrB, IrRhCrB, and PtRhCrB.

In one particular embodiment, the first amorphous capping layer is disposed over the uppermost Si layer of the multi-layer reflective structure and comprised of RuNb, the second amorphous capping layer is disposed over the first amorphous capping layer and is comprised of RuRhN, and the third amorphous capping layer (uppermost capping layer) is comprised of Rh.

In yet another embodiment, the first amorphous capping layer 100a is disposed over the uppermost Si layer 34a of the multi-layer reflective structure 34 and comprised of RuNb, the second amorphous capping layer 100b is disposed over the first capping layer 100a and is comprised of RuN, and the third amorphous capping layer 100c (uppermost capping layer) is comprised of RhN.

Other combinations of the material for each of the amorphous capping layers in the tri-layer are envisioned. The at % amounts of the metals and dopants in each capping layer of the tri-layer are similar to those described above for the single capping layer embodiments.

Moreover, in some embodiments, the uppermost Si layer 34a of the multi-layer reflective structure 34 first undergoes a treatment process 200 as discussed above, or an amorphous layer 50 is formed on the upper surface of the uppermost layer 34a of the multi-layer reflective structure 34 before forming a capping layer. While in other embodiments, the amorphous capping layer is formed over the multi-layer reflective structure by doping or a controlled PVD process.

It should be appreciated that the number of capping layers is not limited to one, two, or three. In other embodiments, more than three capping layers are formed over the multi-layer reflective structure, and each of the capping layers has a thickness range of 1 to 3 nm.

While the foregoing examples include amorphous materials for each capping layer, in certain embodiments, a polycrystalline capping layer is formed if at least one amorphous material is used as the uppermost capping layer to cover the polycrystalline capping layer. In certain embodiments, silicon (Si), silicon nitride (SiN), or tantalum nitride (TaB) is used as a polycrystalline capping material.

As shown in FIG. 12, a polycrystalline capping layer 101 is disposed on the uppermost layer 34a of the multi-layer reflective structure 34. The polycrystalline capping layer 101 has a thickness of 1 to 3 nm. Thereafter, one or more amorphous capping layers 100 a and 100 b are disposed over the polycrystalline capping layer 101. In this embodiment, the treatment of the uppermost layer 34a of the multi-layer reflective structure 34, or the addition of an amorphous layer 50, as discussed above, is not required because a polycrystalline capping layer 101 is disposed on the uppermost layer 34a of the multi-layer reflective structure 34, rather than an amorphous capping layer.

As shown in FIG. 13, a polycrystalline capping layer 101 is disposed between two amorphous capping layers 100a and 100b. Amorphous capping layer 100a is formed on the uppermost layer 34a of the multi-layer reflective structure 34. Thereafter, a polycrystalline capping layer 101 is formed over the capping layer 100a. A second amorphous capping layer 100b is formed over the polycrystalline capping layer 101. In this embodiment, the treatment of the uppermost layer 34a of the multi-layer reflective structure 34, or the addition of an amorphous layer 50, as discussed above, is performed because the amorphous capping layer 100a is formed on uppermost layer 34a.

Although not shown, in other embodiments, more than one polycrystalline capping layer 101 is formed over the uppermost layer 34a and an uppermost amorphous capping layer 100 is formed over one or more polycrystalline capping layers 101.

In the embodiments of FIGS. 12 and 13, the presence of the polycrystalline capping layer 101 can enhance the reflectivity of the multi-layer reflective structure. Moreover, the polycrystalline capping layer 101 is protected from chemical damage since it is protected by one or more amorphous capping layers 100.

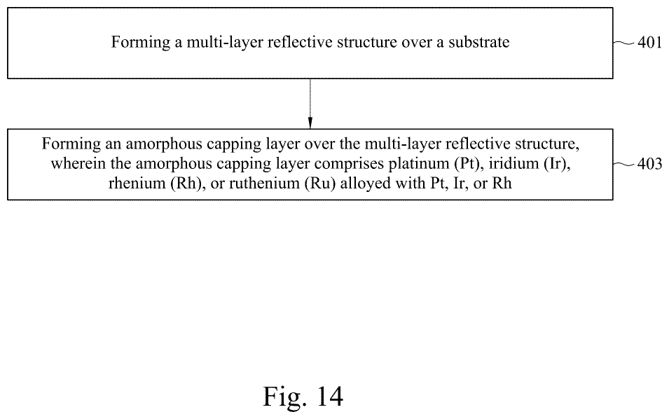

FIG. 14 is a flowchart for a method of fabricating a reflective multilayer structure for lithography according to various aspects of the present disclosure. The method includes a step 401 of forming a multi-layer reflective structure over a substrate. In some embodiments, the reflective structure includes a multilayer structure that is configured to provide a high reflectivity for a predefined radiation wavelength, for example, a reflectivity above a predetermined threshold. The method includes a step 403 of forming an amorphous capping layer over the multi-layer reflective structure. The amorphous capping layer comprises platinum (Pt), iridium (Ir), rhodium (Rh), or ruthenium (Ru) alloyed with Pt, Ir, or Rh. It is understood that in some embodiments, additional processes are performed before, during, or after the steps 401 and 403 of the method to complete the fabrication of the reflective multilayer structure for lithography.

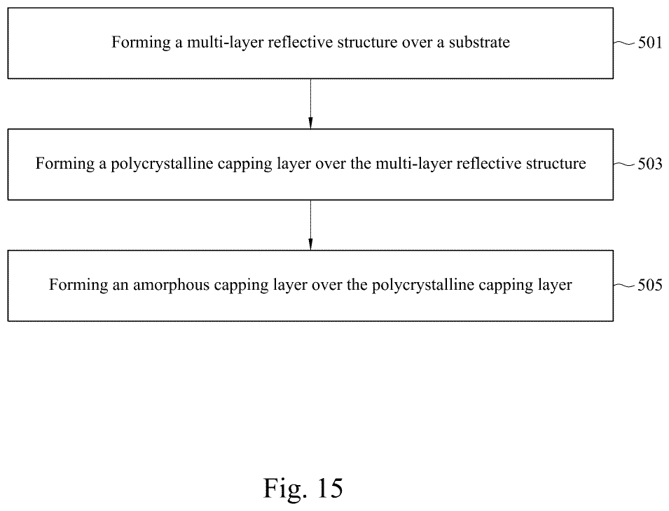

FIG. 15 is a flowchart for a method of manufacturing a lithography mask according to various aspects of the present disclosure. The method includes a step 501 of forming a multi-layer reflective structure over a substrate. The method further includes a step 503 of forming a polycrystalline capping layer over the multi-layer reflective structure. Moreover, the method includes the step 505 of forming an amorphous capping layer over the polycrystalline capping layer. It is understood that in some embodiments, additional processes are performed before, during, or after the steps 501-505 of the method to complete the fabrication of the lithography mask. For reasons of simplicity, additional steps are not discussed herein in detail.

In summary, the present disclosure forms an amorphous capping layer for an EUV lithography mask. Based on the above discussions, it can be seen that the materials of the EUV mask of the present disclosure offer advantages over conventional EUV masks. It is understood, however, that other embodiments may offer additional advantages and not all advantages are necessarily disclosed herein, and that no particular advantage is required for all embodiments. One advantage is that the EUV lithography mask of the present disclosure achieves better film quality for the capping layer compared to conventional EUV lithography masks.

As discussed above, conventional EUV lithography masks form a polycrystalline capping layer, whose grain boundaries are prone to damage as a result of various etching and/or cleaning processes being performed. The damaged polycrystalline capping layer may lead to degraded lithography performance (e.g., worse critical dimensions). In comparison, the EUV lithography masks herein include an amorphous capping layer, comprised of materials that withstand the damaging effects of the various etching and/or cleaning processes much better than polycrystalline capping layers alone. As discussed above, in certain embodiments, a polycrystalline capping layer is combined with an amorphous capping layer. The polycrystalline capping layer enhances the reflectivity of the multi-layer reflective structure, while the amorphous capping layer protects the polycrystalline capping layer from chemical damage.

One aspect of the present disclosure pertains to a method of fabricating a reflective multilayer structure for lithography. The method includes forming a multi-layer reflective structure over a substrate. The method further includes forming an amorphous capping layer over the multi-layer reflective structure. The amorphous capping layer comprises platinum (Pt), iridium (Ir), rhodium (Rh), or ruthenium (Ru) alloyed with Pt, Ir, or Rh. In certain embodiments, the substrate, the multi-layer reflective structure, and the amorphous capping layer are parts of an extreme ultraviolet (EUV) lithography mask. In other embodiments, the method includes forming an amorphous silicon layer, an amorphous silicon oxide layer, or an amorphous silicon nitride layer between the amorphous capping layer and the multi-layer reflective structure. In certain embodiments, the amorphous capping layer is doped with niobium (Nb), chromium (Cr), nitrogen (N), oxygen (O), boron (B), or oxynitride (ON). In other embodiments, a polycrystalline capping layer is formed between the amorphous capping layer and the multi-layer reflective structure. Other embodiments include performing a plasma treatment process on the multi-layer reflective structure before forming the amorphous capping layer. In certain embodiments, the plasma treatment process includes applying Ar plasma, oxygen plasma, or nitrogen plasma. In some embodiments, the method further includes the step of forming a second amorphous capping layer over the amorphous capping layer. In other embodiments, the amorphous capping layer and the second amorphous capping layer include different materials.

Another aspect of the present disclosure pertains to a method of manufacturing a lithography mask. The method includes forming a multi-layer reflective structure over a substrate. The method further includes a polycrystalline capping layer formed over the multi-layer reflective structure. The method includes the step of forming an amorphous capping layer over the polycrystalline capping layer. In certain embodiments, the amorphous capping layer includes platinum, iridium, rhodium, or ruthenium alloyed Pt, Ir, or Rh. In other embodiments, the polycrystalline capping layer includes silicon, silicon nitride, or tantalum nitride. In certain embodiments, the thickness of the amorphous capping layer is in a range of 1 to 3 nanometers. In other embodiments, a second amorphous capping layer is formed over the amorphous capping layer. In certain embodiments, a second amorphous capping layer is formed over the multi-layer reflective structure before forming the polycrystalline capping layer.

Yet another aspect of the present disclosure pertains to a lithography mask. The mask includes a substrate and a multi-layer reflective structure disposed over the substrate. A first amorphous capping layer is disposed over the multi-layer reflective structure. A second amorphous capping layer is disposed over the first amorphous capping layer. The first amorphous capping layer includes a first platinum group metal and the second amorphous capping layer includes a second platinum group metal different from the first platinum group metal. In certain examples, the first amorphous capping layer is doped with niobium, chromium, nitrogen, oxygen, boron, or oxynitride. In other embodiments, the multi-layer reflective structure includes a plurality of pairs of silicon and molybdenum films. In certain embodiments, the second amorphous capping layer includes platinum, iridium, rhodium, or ruthenium (Ru). In some embodiments, a polycrystalline capping layer is covered by at least one of the first amorphous capping layer and the second amorphous capping layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure and that they may make various changes, substitutions, and alterations herein without departing from the spirit and scope of the present disclosure.

1. A method of fabricating a reflective multilayer structure for lithography, comprising:
forming a multi-layer reflective structure over a substrate;
performing a plasma treatment process on an upper surface of the multi-layer reflective structure; and
forming an amorphous capping layer over the plasma-treated upper surface of the multi-layer reflective structure.

2. The method of claim 1, wherein the amorphous capping layer comprises platinum, iridium, rhodium, or ruthenium.

3. The method of claim 1, an uppermost layer of the multi-layer reflective structure comprises silicon.

4. The method of claim 1, wherein the amorphous capping layer is doped with niobium or chromium.

5. The method of claim 1, wherein the plasma treatment process comprises applying argon plasma, oxygen plasma, or nitrogen plasma.

6. The method of claim 5, wherein the plasma treatment process is performed at a temperature in a range from 28 °C to 35 °C.

7. The method of claim 1, wherein a thickness of the amorphous capping layer is in a range of 1 to 6 nanometers.

8. A method of manufacturing a lithography mask, comprising:
forming a multi-layer reflective structure;
forming a polycrystalline capping layer over the multi-layer reflective structure; and
forming a first amorphous capping layer over the polycrystalline capping layer,
wherein the first amorphous capping layer comprises platinum (Pt), iridium (Ir), rhodium (Rh), or ruthenium (Ru) alloyed with Pt, Ir, or Rh.

9. The method of claim 8, wherein the polycrystalline capping layer comprises silicon (Si), silicon nitride, or tantalum nitride.

10. The method of claim 8, further comprising: forming a second amorphous capping layer over the first amorphous capping layer.

11. The method of claim 8, further comprising forming an additional amorphous capping layer over the multi-layer reflective structure before forming the polycrystalline capping layer.

12. The method of claim 8, wherein the polycrystalline capping layer has a thickness of 1 to 3 nanometers.

13. The method of claim 8, further comprising:
patterning an absorber layer over the amorphous capping layer.

14. A lithography mask, comprising:
a multi-layer reflective structure;
a first amorphous capping layer over the multi-layer reflective structure, wherein the first amorphous capping layer comprises a platinum group metal or platinum group metal alloy;
a second amorphous capping layer over the first amorphous capping layer; and
a patterned absorption layer over the second amorphous capping layer.

15. The lithography mask of claim 14, wherein the first amorphous capping layer comprises RuNb and the second amorphous capping layer comprises rhodium (Rh).

16. The lithography mask of claim 14, wherein the first amorphous capping layer is doped with nitrogen, boron, oxygen, or an oxynitride.

17. The lithography mask of claim 14, wherein the multi-layer reflective structure includes a plurality of pairs of silicon and molybdenum films.

18. The lithography mask of claim 17, wherein an uppermost layer of the multi-layer reflective structure comprises silicon.

19. The lithography mask of claim 14, wherein the second amorphous capping layer includes a platinum group metal or platinum group metal alloy.

20. The lithography mask of claim 14, wherein a thickness of the second amorphous capping layer is 1 to 3 nanometers.
